(19) United States
(12) Patent Application Publication
(10) Pub. No.: US 2023/0110359 A1
(43) Pub. Date: Apr. 13, 2023

(54) Method and System for Controlling Temperature during Crystal Growth

(71) Applicant: XUZHOU XINJING SEMICONDUCTOR TECHNOLOGY CO., LTD, Xuzhou, Jiangsu (CN)

(72) Inventors: Mo HUANG, Xuzhou, Jiangsu (CN); Linyan LIU, Xuzhou, Jiangsu (CN); Haitang GAO, Xuzhou, Jiangsu (CN); Yi CHEN, Xuzhou, Jiangsu (CN); Qi LIU, Xuzhou, Jiangsu (CN); Shuangli WANG, Xuzhou, Jiangsu (CN)

(21) Appl. No.: 17/913,173

(22) PCT Filed: Apr. 6, 2021
(86) PCT No.: PCT/CN2021/085533

§ 371 Date: Sep. 21, 2022

(30) Foreign Application Priority Data
Apr. 20, 2020 (CN) 202010311608.1

(51) Int. Cl. C30B 15/20; C30B 15/22; C30B 15/14

(52) U.S. Cl. CPC C30B 15/206; C30B 15/22; C30B 15/14; C30B 29/06

(57) ABSTRACT

The disclosure discloses a method and a system for controlling temperature during crystal growth. The method includes that: the power of each of the heaters is constantly adjusted and simulating is performed by software to calculate the thermal field correspondingly at a solid-liquid interface and vicinity of the solid-liquid interface; the thermal field is coupled with a moving grid to determine whether the solid-liquid interface and the total thermal energy both reach thermal equilibrium; the power of each of the heaters that enables both the solid-liquid interface and the total thermal energy to reach the thermal equilibrium is stored and a thermal equilibrium diagram is drawn based on the power of each of the heaters; and during crystal growth, the power of each of the heaters is selected from the thermal equilibrium diagram which is drawn to control the temperature gradient at the solid-liquid interface.

### CROSS-REFERENCE TO RELATED APPLICATION

The present disclosure claims the priority of Chinese Patent Application No. 202010311608.1, filed to the China National Intellectual Property Administration on Apr. 20, 2020 and entitled “Method and System for Controlling Temperature during Crystal Growth”, which is incorporated herein its entirety by reference.

### TECHNICAL FIELD

The present disclosure generally relates to a method and a system for controlling temperature during crystal growth, and more particularly, to a method and a system for controlling an axial temperature gradient at a solid-liquid interface by adjusting a power of a heater during crystal growth.

### BACKGROUND

As the critical dimension of a semiconductor device becomes smaller and smaller, the quality requirements of a semiconductor silicon wafer in a semiconductor factory become higher and higher, especially for the requirements of surface defects (localized light-scatter, LLS), flatness and surface and body metal impurities of the silicon wafer. In order to reduce the number of surface defects of the silicon wafer, a silicon wafer manufacturer attempts to control the thermal history of silicon single crystal growth to eliminate crystal defects generated during crystal growth, so as to reduce the number of surface defects. At present, how to eliminate crystal defects during crystal growth is explained by the theory proposed by Voronkov. It is pointed out by Voronkov that if the crystal defects caused by single crystal growth are to be eliminated during crystal growth, the axial temperature gradient of crystal at the solid-liquid interface needs to be kept uniform along the radial direction, and the ratio of crystal growth rate to the axial temperature gradient at the solid-liquid interface must be controlled within a certain range. In other words, in order to eliminate the crystal defects caused by single crystal growth during crystal growth, the ratio V/G of the crystal growth rate to the axial temperature gradient at the solid-liquid interface must be controlled within a certain range.

However, in the actual crystal growth process, the crystal growth rate can be set by a program, but the axial temperature gradient of the crystal at the solid-liquid interface cannot be directly obtained by a measurement method. Therefore, other measurement methods must be developed to obtain the value indirectly, so that the crystal growth process can be monitored and controlled in real time.

CN 108754599A discloses a method for controlling the growth temperature of silicon single crystal based on finite element numerical simulation. Same solves the problem that the existing silicon single crystal growth control method in a conventional art cannot meet crystal temperature control, resulting in crystal dislocation defects. However, the finite element simulation analysis is too computationally intensive, and same only simulates crystals in a certain axial range. Moreover, the heat source is only distributed in this axial range, which is quite different from the actual crystal growth environment and hence is not suitable for direct temperature control in actual crystal growth.

CN 100374628C discloses a method for producing a silicon single crystal, which includes that: a single crystal is drawn from a melt in a rotating crucible by a Zokolaski method, and the single crystal grows at a growth crystal surface; and the single crystal and the crucible are rotated in the same direction, and the heat is supplied to the center of the growth crystal surface through a heat source acting on the center of the growth crystal surface, so that the heat reaching the center of the growth crystal surface per unit time is more than the heat reaching an edge area of the growth crystal surface around the center. However, the production method of silicon single crystal in the disclosure does not specify how to adjust the power of each of the heaters.

Therefore, there is a need for a method that can greatly reduce the calculation amount during actual crystal growth and can adjust the power of each of the heaters in real time through automatic control software to control the axial temperature gradient at the solid-liquid interface.

### SUMMARY

In view of the aforementioned background, the disclosure provides a method for controlling temperature during crystal growth, which include that: power of each of heaters is constantly adjusted and simulating is performed by software to calculate a thermal field correspondingly at a solid-liquid interface and vicinity thereof; the thermal field is enabled to be coupled with a moving grid to determine whether the solid-liquid interface and a total thermal energy both reach thermal equilibrium; the power of each of the heaters that enables both the solid-liquid interface and the total thermal energy to reach the thermal equilibrium is stored and a thermal equilibrium diagram is drawn based on the power of each of the heaters; and during the crystal growth, the power of each of the heaters is selected from the thermal equilibrium diagram which is drawn to control the temperature gradient at the solid-liquid interface. In one embodiment, the method further includes that a liquid level of metal is kept unchanged by continuous feeding during the crystal growth.

In one embodiment, during the crystal growth, the power of each of the heaters is selected from the thermal equilibrium diagram which is drawn includes that: the power of each of the heaters that meets a condition for growing a perfect crystal is selected from the thermal equilibrium diagram which is drawn during the crystal growth. In one embodiment, the condition for growing the perfect crystal includes V/G=0.112−0.142 mm²/min·° C., preferably V/G=0.117−0.139 mm²/min·° C., and Gc>=Ge, and V represents a crystal growth rate, G represents axial temperature gradient at the solid-liquid interface, Gc represents G at a crystal center, and Ge represents G at a crystal edge.

In one embodiment, the method further include that a crystal growth rate is determined in real time during the crystal growth. In one embodiment, the thermal equilibrium diagram is a plurality of thermal equilibrium diagrams corresponding to a plurality of crystal growth rates. Moreover, during the crystal growth, the power of each of the heaters is selected from the thermal equilibrium diagram which is drawn includes that: the power of each of the heaters is selected from the thermal equilibrium diagram corresponding to the crystal growth rate determined in real time in the plurality of the thermal equilibrium diagrams during the crystal growth. In one embodiment, the crystal growth rate is determined in real time includes that: the crystal growth rate is detected in real time using a sensor. In another embodiment, the crystal growth rate is determined in real time includes that: a preset crystal growth rate is retrieved from a device associated with the crystal growth.

In one embodiment, the power of each of the heaters is constantly adjusted includes that: the power of two or three different heaters selected from a group including a side heater, a bottom heater and an upper heater is adjusted at a predetermined interval or randomly. In another embodiment, the power of each of the heaters is constantly adjusted includes that: the power of one heater selected from a group including a side heater, a bottom heater and a upper heater is set to be each of a predetermined number of values, the power of the other two heaters in the group is adjusted at a predetermined interval or randomly.

In one embodiment, when the power of multiple groups of the heaters meeting a thermal equilibrium condition exists in the thermal equilibrium diagram, during the crystal growth, the power of one group of the heaters is randomly selected from the power of the multiple groups of the heaters to control the temperature gradient at the solid-liquid interface, or the power of one group of the heaters, which is closest to current power of each of the heaters as a whole, is selected from the power of the multiple groups of the heaters to control the temperature gradient at the solid-liquid interface, or the power of the following group of the heaters is selected from the power of the multiple groups of the heaters to control the temperature gradient at the solid-liquid interface: after the heaters are controlled according to same, a thermal field distribution of a system is closest to a current thermal field distribution.

In one embodiment, the thermal equilibrium diagram is in the form of a table that stores power of multiple groups of the heaters meeting a thermal equilibrium condition. In one embodiment, the thermal equilibrium diagram is in the form of a graph formed by connecting power of multiple groups of the heaters meeting a thermal equilibrium condition. In one embodiment, in the thermal equilibrium diagram, two of power of a side heater, power of a bottom heater and power of an upper heater are in a linear relationship, and during the crystal growth, two of the power of the side heater, the power of the bottom heater and the power of the upper heater are adjusted according to the linear relationship.

The disclosure also provides a system for controlling temperature during crystal growth, which include: a single crystal furnace, including heaters and a continuous feeder configured to keep a liquid level of metal unchanged; a processor; a memory on which an instruction is stored, the instruction, when executed, causing the processor to execute the method for controlling the temperature during the crystal growth described in the disclosure; and a controller coupled with the single crystal furnace, the heaters and the continuous feeder therein and the memory so as to control them. In one embodiment, the system can further include a sensor configured to detect a crystal growth rate in real time.

The features, aspects and advantages of the present disclosure will be apparent by reading the following detailed description together with the accompanying drawings, and the accompanying drawings are briefly described below. This disclosure includes any combination of two, three, four or more features or elements set forth in the disclosure, regardless of whether such features or elements are clearly combined or otherwise recorded in the specific example implementations described herein in other manners. The disclosure is intended to be read holistically so that any separable features or elements of the disclosure, in any of its aspects and example implementation modes, shall be regarded as combinable, unless the context of the disclosure clearly dictates otherwise.

### BRIEF DESCRIPTION OF THE DRAWINGS

Therefore, the disclosure has been generally described, and reference is now be made to the accompanying drawings, which are not necessarily drawn to scale, and herein:

FIG. 1 illustrates a system for controlling temperature during crystal growth according to an embodiment.

FIG. 2 illustrates a schematic diagram of a flow direction of heat generated by each of heaters during crystal growth according to an embodiment.

FIG. 3 illustrates a flowchart of a method for controlling temperature during crystal growth according to an embodiment.

FIG. 4 illustrates a resulting thermal equilibrium diagram according to an embodiment.

FIGS. 5A-5D illustrate selections of power of each of heaters meeting a condition for growing a perfect crystal according to an embodiment.

### DETAILED DESCRIPTION OF THE EMBODIMENTS

As used herein, for example, singular forms “a/an”, “one”, and “the” can also include the plural forms, unless otherwise specified in the context. Herein, reference can be made to quota metrics, values, relationships and so on. Unless otherwise stated, any one or more, if not all of them, can be absolute or approximate to account for acceptable variations that can occur, such as those due to engineering tolerances, etc. It is to be pointed out that when ordinal numbers “first”, “second” or “third” herein are used to modify a thing, it does not mean that the thing must be “first”, “second” or “third” in chronological order or spatial order, but only for the convenience of description. In addition, unless otherwise specified, things described by ordinal numbers “first”, “second” or “third” can be interchanged without exceeding the scope of the disclosure. It is also be pointed out that, as commonly understood by those of ordinary skill in the art, the term “perfect crystal” or “defect-free crystal” used herein does not mean an absolutely perfect crystal or a crystal without any defects, but allows a very small amount of one or more crystal defects, which are not enough to make some electrical or mechanical characteristics of the crystal or the resulting wafer change greatly and the performance of an electronic device made of same deteriorate.

Some implementation modes of the present disclosure are now described more fully hereinafter with reference to the accompanying drawings, and in the accompanying drawings, some but not all implementation modes of the disclosure are shown. In fact, various implementation modes of the disclosure can be embodied in many different forms and shall not be construed as limited to the implementation modes set forth herein. On the contrary, these example implementation modes are provided to better convey the scope of the disclosure to those skilled in the art.

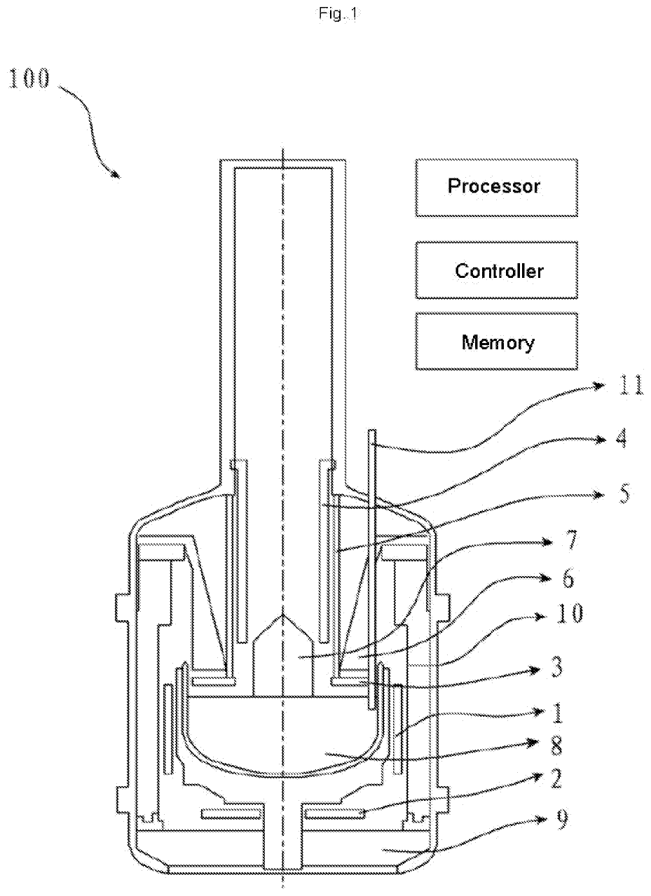

FIG. 1 illustrates a system 100 for controlling temperature during crystal growth according to an embodiment. The system 100 includes a processor, a memory, a controller and a single crystal furnace. A processor in the system 100 represents a processing unit which can execute an Operating System (OS) and an application. The processor can include one or more separate processors. Each separate processor can include a single processing unit, a multi-core processing unit, or a combination. The processing unit can be a main processor such as a Central Processing Unit (CPU), a peripheral processor such as a Graphics Processing Unit (GPU) or a combination. The memory in the system can include different memory types, such as a volatile memory and a non-volatile memory. The volatile memory can include a dynamic volatile memory, such as a Dynamic Random Access Memory (DRAM) or some variants, such as a Synchronous DRAM (SDRAM). The nonvolatile memory device is a block addressable memory device, such as NAND or NOR technology. Therefore, the memory device can also include a nonvolatile device developed in the future, such as a three-dimensional cross-point memory device, another byte addressable nonvolatile memory device, or a memory device using a chalcogenide compounds phase change material (for example, chalcogenide compounds glass). The memory and processor in the system 100 can be communicatively coupled wirelessly or by wire. The memory in the system 100 can store a computer readable instruction and data. The instruction, when executed, enables the processor in the system 100 to perform the method described herein for controlling temperature during crystal growth. The controller in the system 100 can include a controller circuit or device for one or more memories of the system 100 and a controller circuit and device for controlling the single crystal furnace. The memory controller can access the memory, and the memory controller can generate control logic of a memory access command in response to operation execution of the processor. The controller circuit and device for controlling the single crystal furnace includes one or more sub-controller circuits and devices, which are configured to control such things as crystal growth rate (V), heater power (for example, power of a side heater, power of an upper heater and power of a bottom heater), cooling rate of a crystal, and supply amount and supply rate of metal. The controller in the system 100 is coupled with the processor and the memory in a wireless or wired manner, so that the controller can be dominated by the processor to perform corresponding control. It is noted that although not shown in FIG. 1, any two or more of the processor, memory, controller and single crystal furnace in the system 100 can be electrically or mechanically coupled together as required.

The single crystal furnace described in FIG. 1 is a single crystal furnace that uses a Continuous Czochralski method (CCZ method) to grow a single crystal. However, it is to be pointed out that the method and system described herein for controlling temperature during crystal growth are not limited to growth of the single crystal by the Czochralski method. In other words, the method described herein can be adapted to other methods for growing the single crystal, such as a FZ method, and still fall within the scope of the present disclosure. The CCZ single crystal furnace shown in FIG. 1 includes a thermal insulation layer 9 with low thermal conductivity, a graphite support 10, a heat shield (or reflector) 6, a cooling component 4, a continuous feeder 11, metal 8, an electrode foot 5, an upper heater 3, a side heater 1, a bottom heater 2 and a crystal ingot 7 which is pulled.

In the process of growing a single crystal, the power of the upper heater 3, the power of the side heater 1 and the power of the bottom heater 2 are respectively configured to generate appropriate heat to maintain the metal in a molten state. The positions of the upper heater 3, the side heater 1, and the bottom heater 2 in FIG. 1 are schematic, which does not mean that the upper heater 3 must be located at the uppermost part of the single crystal furnace. Similarly, the bottom heater 2 is not necessarily located at the bottom of the single crystal furnace. In other words, the positions of the upper heater 3, the side heater 1, and the bottom heater 2 in FIG. 1 are relative. In addition, only a pair of upper heaters 3, a pair of side heaters 1 and a pair of bottom heaters 2 are shown in FIG. 1 for illustrative purposes. Actually, any number of upper heaters 3, side heaters 1 and bottom heaters 2 can be included in the single crystal furnace. In some embodiments, one or both of the upper heater 3, the side heater 1 and the bottom heater 2 can be omitted. In addition, the upper heater 3, the side heater 1 and the bottom heater 2 can be the same or different types of heaters, and they can have the same or different heating power ranges.

The thermal insulation layer 9 with low thermal conductivity can be made of a known traditional thermal insulation material such as graphite and carbon felt, and a new thermal insulation material such as a vacuum plate and an aerogel blanket. The thermal insulation layer 9 with low thermal conductivity enables the heat generated by each of the heaters mainly concentrate in the metal, thus increasing the utilization efficiency of heat. The heat shield 6 can include a plurality of layers, such as an outer heat shield layer, an inner heat shield layer and an intermediate insulation layer, so as to reduce heat loss.

In the process of growing the single crystal, each of the heaters is turned on and respective power is adjusted. Consequently, the crystal ingot 7 is pulled out while the metal 8 rotates. The cooling component 4 is turned on to keep the crystal ingot 7 which is pulled below the melting point of the crystal without being reheated and molten. The cooling component 4 (for example, water) can be continuously circulated, so that the crystal ingot 7 is always cooled by the cooling component 4 with extremely low temperature (for example, 0° C.). In addition to or in combination with water cooling, the cooling component 4 can also adopt any other known and future developed cooling methods, such as air cooling. In order to maintain a certain amount of metal 8, the continuous feeder 11 continuously adds the metal, granular material or small block material 8 into the single crystal furnace. The amount of metal added by the continuous feeder 11 every time or at set intervals can be automatically controlled via an automatic control method known in the industry (for example, a PID method) to maintain a substantially constant metal level. Although not shown in detail in FIG. 1, the single crystal furnace can also include other components, such as, but not limited to, a magnetic component for generating a magnetic field to increase the temperature gradient, a component for controlling the rotation speed of the metal, and a sensor for measuring the crystal growth rate and metal level.

In the process of single crystal growth by Czochralski method, the success and quality of single crystal growth are determined by the temperature distribution of the thermal field. The thermal field with proper temperature distribution not only makes the single crystal grow smoothly, but also has high quality. If the temperature distribution of the thermal field is not very reasonable, it is easy to produce various defects in the process of growing the single crystal, which affects the quality. In serious cases, morphotropism occurs and no single crystal grows out. Therefore, during the crystal growth, the most reasonable thermal field must be configured according to the growth device, so as to ensure the quality of the produced single crystal. In the Czochralski single crystal growth process, the temperature gradient is generally used to describe the temperature distribution of the thermal field. Herein, the temperature gradient at the solid-liquid interface is the most critical.

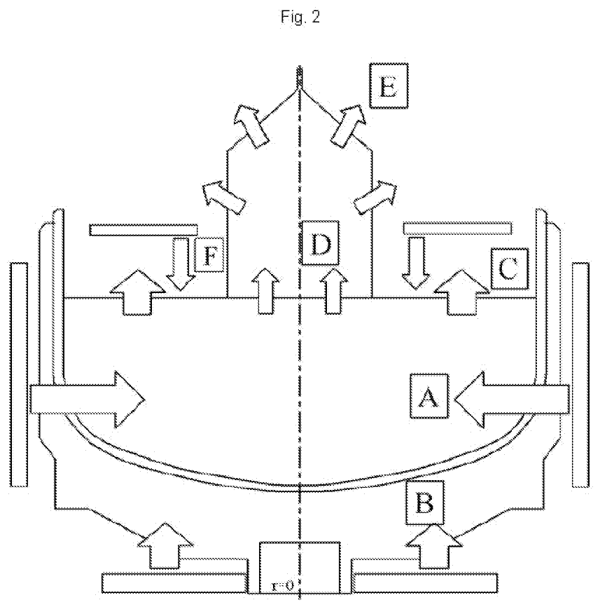

FIG. 2 illustrates a schematic diagram of a flow direction of heat generated by each of the heaters during crystal growth according to an embodiment. The upper heater is located below the heat shield 6, as shown in FIG. 1. Herein, the fact that the upper heater is located below the thermal shield 6 can mean that the upper heater is located directly below the thermal shield 6, or on the lower side or below the side of a wrapping apparatus of the thermal shield. Or only the side heater and the bottom heater can be used without the upper heater. It is to be seen from FIG. 2 that the heat B generated by the bottom heater flows upward and passes through a crucible containing the metal and is conducted into the metal. The heat A generated by the side heater is conducted into the metal through the crucible wall in the radial direction. The heat F generated by the upper heater located below the heat shield 6 is conducted to the interface of the crystal ingot. Part D of the heat in the metal is conducted into the crystal ingot through the solid-liquid interface. The other part C is conducted into the single crystal furnace via the surface of the metal. Moreover, part E of the heat conducted into the crystal ingot further diffuses into the single crystal furnace through the surface of the crystal ingot.

In order to simulate the thermal field distribution in the single crystal furnace, a numerical simulation method is usually used. The numerical simulation is to support a real (and expensive) experiment using detailed information provided by computer calculations at a low cost. Since the numerical simulation provides an approximate real process, it is easy to judge the influence of any type of changes (geometric size, thermal insulation material, heater, peripheral environment, etc.) on crystal quality using this technology. Lots of software is used for simulating the thermal field of the single crystal furnace, including but not limited to process-oriented simulation software FEMAG, CGSIM, COMSOL, etc. In the disclosure, the power of each of the heaters is constantly adjusted and simulating is performed by the CGSIM software to calculate the thermal field correspondingly, and the power of each of the heaters meeting the thermal equilibrium condition is selected therefrom to draw the thermal equilibrium diagram. In the actual crystal growth process, the power of each of the heaters can be directly controlled according to the obtained thermal equilibrium diagram.

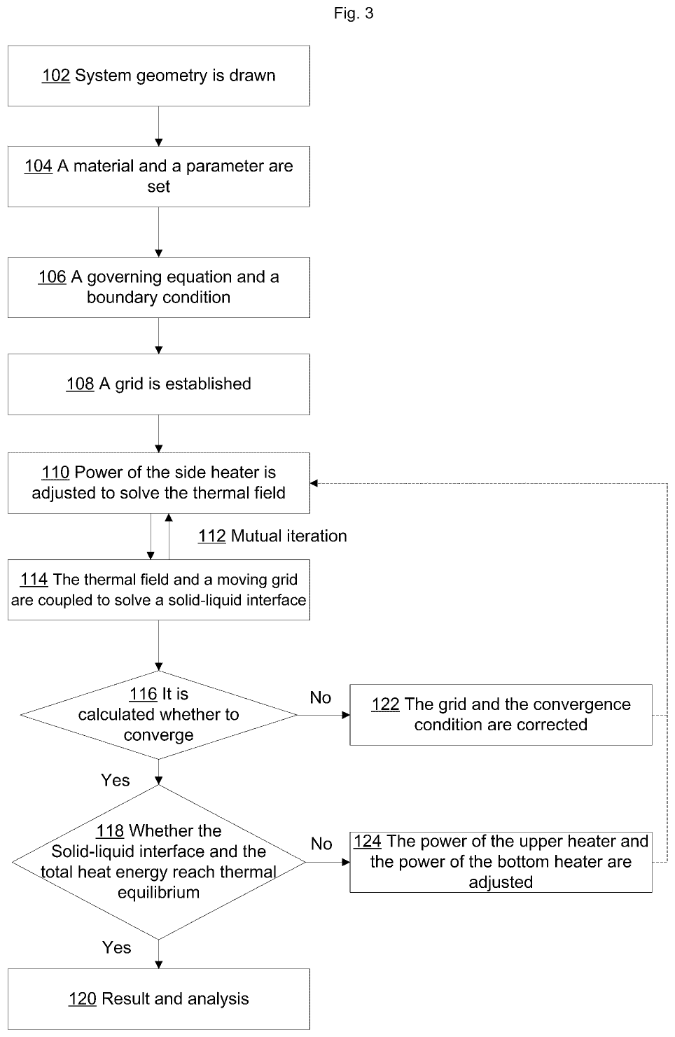

FIG. 3 illustrates a flowchart of a method for controlling temperature during crystal growth according to an embodiment. The idea of the method is that: the power of the side heater, the power of the upper heater and the power of the bottom heater are constantly changed, and the thermal field distribution on the corresponding solid-liquid interface and vicinity thereof in the single crystal furnace is simulated and calculated by software; and a combination of the power of each of the heaters meeting the thermal equilibrium condition is selected from all combinations of the power of the side heater, the power of the upper heater and the power of the bottom heater, and a thermal equilibrium diagram is drawn based thereon. In one embodiment, the method includes that: the power of the side heater is set to be a certain value, and for the power of the side heater, the power of the upper heater and the power of the bottom heater are constantly changed, the power of the upper heater and the power of the bottom heater being traversed in a certain range at a certain interval, or the power of the upper heater and the power of the bottom heater being randomly changed by software to a predetermined number in a certain range; and then, the power of the side heater is set to another value, and the above process is repeated until the corresponding power of the upper heater and the corresponding power of the bottom heater for the power of all the predetermined number of side heaters are calculated to meet the thermal equilibrium condition. In another embodiment, the method can also include that: the power of the upper heater or the power of the bottom heater is set, while the power of the other two heaters is constantly changed, and other steps remain unchanged.

The “thermal equilibrium diagram” mentioned in the disclosure means all combinations of the power of the upper heater, the power of the bottom heater and the power of the side heater that meet the thermal equilibrium condition. In one embodiment, the thermal equilibrium diagram can be a point, a line, a surface or a body in a three-dimensional space with the power of the upper heater, the power of the bottom heater and the power of the side heater as coordinate axes, respectively. In one embodiment, the thermal equilibrium diagram is in the form of a table, in which all combinations of the power of the upper heater, the power of the bottom heater and the power of the side heater meeting the thermal equilibrium condition are recorded. In another embodiment, the thermal equilibrium diagram can be a plurality of thermal equilibrium diagrams related to the crystal growth rate V.

In one embodiment, the method disclosed herein further includes that the power of each of the heaters is selected directly according to the thermal equilibrium diagram during the crystal growth and the axial temperature gradient at the solid-liquid interface is controlled accordingly. In another embodiment, based on the current crystal growth rate, a thermal equilibrium diagram corresponding to the current crystal growth rate can be selected from a plurality of thermal equilibrium diagrams related to the crystal growth rate, and the axial temperature gradient at the solid-liquid interface can be controlled based thereon.

The specific steps of the method are described in detail below with reference to FIG. 3. In S102, a geometric structure of related components in the single crystal furnace is drawn, including the shape and size of a crucible containing metal and a crystal ingot pulled out, for example. It is to be pointed out that the present disclosure is applicable to the growth of crystals of any desired size, including, for example, 4 inches, 6 inches, 8 inches and 12 inches. In S104, a material and a parameter are set, including setting the material, specific heat capacity, density and the like of the single crystal to be grown. The method for controlling the power of each of the heaters in a single crystal furnace disclosed in the disclosure is suitable for controlling the power of each of the heaters not only in the process of growing the monocrystalline silicon but also in the process of growing other single crystals (such as sapphire). In addition, the method disclosed in the disclosure is not limited to growing a single crystal at a specific crystal surface, but can be applied to growing a single crystal at any crystal surface.

In S106, a governing equation and a boundary condition are established. When the thermal field in the single crystal furnace is simulated by software, it is assumed that a basic model is two-dimensional axisymmetric. That is, the temperature of a position which is axisymmetric around the crystal changes to zero, as shown in formula (1). Assuming that the fluid is incompressible Newtonian fluid and the gas satisfies an ideal equation of gas state, according to the theory of heat conduction and fluid mechanics, the thermal field and flow field are used for coupling calculation. Herein, the heating source of the thermal field is each of the heaters, which generates thermal energy Q to generate resistance heat in the form of heat conduction (formula (2)). The resistance heat is transferred to the whole model through a boundary equation of face-to-face thermal radiation. The boundary equation includes the following formulas: crystal surface (formula (3)), liquid level of metal (formula (4)), and another surface (formula (5)). All solids and fluids transfer heat energy inside an object through heat conduction (formula (6)). The periphery of the model is used for runner heat dissipation, assuming that the periphery of the model keeps a constant temperature of 300K (formula (7)).

$$∇ T \cdot \vec{n} = 0 \qquad ( 1 )$$

$$∇ \cdot ( - {k}_{h} ∇ T ) = Q \qquad ( 2 )$$

$$- {k}_{c} \frac{\partial {T}_{c}}{\partial n} = {σε}_{c} ( {T}_{c}^{4} - {T}_{amb , c}^{4} ) \qquad ( 3 )$$

$$- {k}_{l} \frac{\partial {T}_{l}}{\partial n} = {σε}_{l} ( {T}_{l}^{4} - {T}_{amb , l}^{4} ) \qquad ( 4 )$$

$$- {k}_{s} \frac{\partial {T}_{s}}{\partial n} = {σε}_{s} ( {T}_{s}^{4} - {T}_{amb , s}^{4} ) \qquad ( 5 )$$

$$∇ \cdot ( - {k}_{s} ∇ T ) = 0 \qquad ( 6 )$$

$${T}_{out} = 300 K \qquad ( 7 )$$

Thereafter, the method in FIG. 3 proceeds to S108 to build and divide a grid, for example, by a method well known to those skilled in the art. At S110, the power of the side heater is adjusted and the thermal field is solved. In one embodiment, when the method in FIG. 3 is first run, at S110, the power of each of the heaters can be set (including setting the power of the side heater, the power of the upper heater and the power of the bottom heater) and the thermal field correspondingly at the solid-liquid interface and vicinity thereof can be solved. When the method is run again at S110, the step of adjusting the power of the side heater and solving the thermal field correspondingly at the solid-liquid interface and vicinity thereof is executed.

The continuous feeder 11 continuously adds the metal 8 to the single crystal furnace, so that the metal in the crucible maintains a certain amount. However, in the actual crystal growth process, the interface between the crystal ingot and the liquid level of the metal changes dynamically. The moving boundary involves stefan problem. For stefan boundary problem, a solid-liquid equation and a surface-surface equation can be established, and a setting value of the ambient temperature is obtained through repeated iterations. At S114, the thermal field and the flow field are coupled with each other by an energy equation (formula (B)), and the thermal field at the solid-liquid interface and vicinity thereof is solved by mutual iteration with the total thermal energy Q and the crystal growth rate V via the boundary equation (stefan) at S112. A limit on the number of iterations can be set for repeated iterations at S112. If the convergence cannot be reached after the limit is exceeded, the method proceeds to S122.

ρcₚ\vec{u}·(∇T)+∇·(−k∇T)=0 (8)

After the coupling equilibrium between the thermal field and the flow field of the whole model is solved, at S116, it is judged whether the calculation converges. If a convergence value is not obtained, the method proceeds to S122 to modify the grid and set a new convergence condition. If the convergence value is calculated, the temperature field distribution and velocity field distribution are obtained. The solid-liquid interface shape and power distribution can also be obtained. The method proceeds to S118 to judge whether both the solid-liquid interface and the total thermal energy are in equilibrium. If it is judged at S118 that both the solid-liquid interface and the total thermal energy are in equilibrium, the method proceeds to S120 to store the power of each of the heaters and analyze a result. In one embodiment, at S120, the obtained power of each of the heaters can be stored in a memory in the system 100 in the form of a table. In another embodiment, at S120, the obtained power of multiple groups of the heaters can be analyzed, and the law of the power of each of the heaters meeting the thermal equilibrium condition can be counted, including the range of the power of each of the heaters and the law of power change of other heaters when the power of one heater changes, including a linear change, an exponential change or an irrelevant change. In another embodiment, statistics and analysis of the result can be performed in the processor in the system 100 and can also be performed on other computing devices outside the system 100. In another embodiment, a data analysis method and model commonly used in statistics including machine learning can be applied to the statistics and analysis of the result. In one embodiment, at S120, the statistics and analysis of the result includes that the thermal field distribution at the solid-liquid interface and vicinity thereof corresponding to the power of each of the heaters meeting the thermal equilibrium condition of the system is recorded, including the axial temperature gradient at the corresponding solid-liquid interface, including the temperature gradient Ge at the edge and the temperature gradient Gc at the center in the radial direction of the crystal. If at S118, it is judged that one or both of the solid-liquid interface and the total thermal energy are not in equilibrium, the power of the upper heater and the power of the bottom heater are readjusted, and the above process is repeated until the power of a predetermined range or number of upper heaters and the power of the bottom heater are traversed according to a certain rule (for example, at a certain interval or randomly) for the power of the side heater. Thereafter, the power of the side heater is set to another value, and the above process is repeated.

It is to be pointed out that the method of the flowchart in FIG. 3 is only schematic, and a certain step or some steps in the method can be omitted or executed many times. Furthermore, it is to be pointed out that the method of the flowchart in FIG. 3 is only for convenience of explanation, but not exhaustive, the steps herein can be split into multiple sub-steps to be executed, and there can be additional steps therein. In addition, although, in the method of the flowchart in FIG. 3, the power of the side heater is set to be a certain value to constantly change the power of the upper heater and the power of the bottom heater so as to calculate the power of each of the heaters meeting the thermal equilibrium condition, in other embodiments, any one or both of the power of the side heater, the power of the upper heater and the power of the bottom heater can also be set to constantly change the other two or one, and then the power of each of the heaters meeting the thermal equilibrium condition of the system is calculated. In addition, in other embodiments, any one of the side heater, the upper heater and the bottom heater can also be omitted.

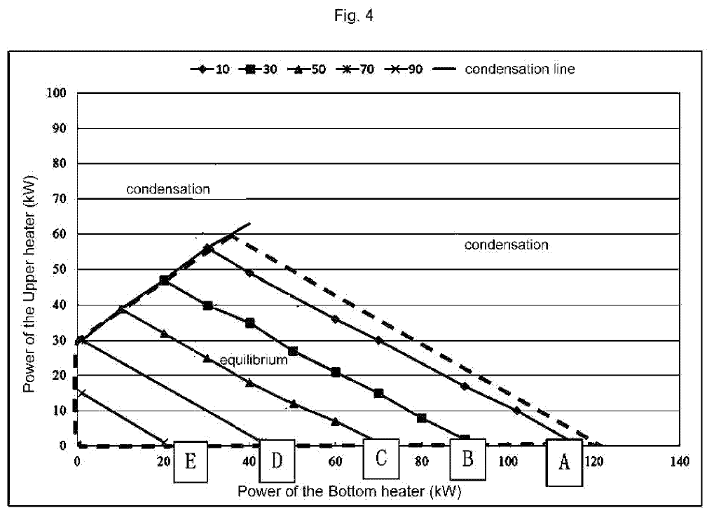

FIG. 4 illustrates a resulting thermal equilibrium diagram according to an embodiment. In the disclosure, the power of the side heater is set to 10, 30, 50, 70 and 90KW respectively, while the power of the upper heater and the power of the side heater are constantly changed to calculate the thermal equilibrium diagram. When the power of the side heater is set to 10KW, the power of the upper heater and the power of the bottom heater are adjusted so that both the solid-liquid interface and the total heat energy are in thermal equilibrium. Points meeting the thermal equilibrium condition are drawn in the plane with the power of the upper heater and the power of the bottom heater as horizontal and vertical coordinates, respectively, and connected into a line, as shown by line A in FIG. 4. Other B, C, D and E lines are obtained by analogy.

It is to be seen from FIG. 4, that lines A, B, C, D and E are basically parallel straight lines. In other words, when the power of the side heater is set to be a certain value, the power of the upper heater and the power of the bottom heater meeting the thermal equilibrium condition are in a linear relationship. The power of the side heater is constantly adjusted to obtain a thermal equilibrium area, such as an area enclosed by a dotted line near the lower left corner of FIG. 4. That is, when the power of the upper heater and the power of the bottom heater are in the thermal equilibrium area, a crystal can grow out smoothly. It is to be noted that what is calculated in the experiment is the combination of the power of each of the heaters meeting the thermal equilibrium condition, that is, points marked with different symbols in the thermal equilibrium area in FIG. 4. The boundary of the thermal equilibrium area is inferred from the distribution trend of many points meeting the thermal equilibrium condition calculated in the thermal equilibrium diagram. The boundary surrounding the thermal equilibrium area consists of four dotted-line parts. The dotted-line part coinciding with the abscissa axis (that is, the power of the bottom heater) indicates that the power of the upper heater is zero. The dotted-line part coinciding with the ordinate axis (that is, the power of the upper heater) indicates that the power of the bottom heater is zero. The area that continues to extend beyond the top dotted-line part (coinciding with a condensation line indicated by a solid line) is a condensation area, which means that the power of the upper heater is too high, but the power of the bottom heater is too low. Since the temperature is too low and the energy of the metal is insufficient, the bottom solidifies in advance, which destroys the thermal equilibrium of the crystal growth area and does not facilitate the crystal growth environment. The top dotted-line part is inclined upward. This means that the greater the power of the side heater (that is, the closer to the lower left of the thermal equilibrium area) is, the lower the power of an extreme bottom heater meeting the thermal equilibrium condition is. This is also in line with the experience of adjusting the power of each of the heaters in the actual crystal growth process. The dotted-line part on the rightmost side indicates that the power of the side heater is zero. As the side heater is the main heater and supports the energy source of the whole system, the continuous extension beyond the dotted-line part on the rightmost side also leads to condensation, and the condensation starts from the side surface.

In order to verify whether the points on lines A, B, C, D and E in the thermal equilibrium diagram shown in FIG. 4 enable the system to reach thermal equilibrium, the power of the upper heater is fixed to 10 KW in the disclosure. When the power of the side heater is 10, 30, 50, 70 and 90 KW, respectively, the power of the bottom heater meeting the thermal equilibrium condition is simulated and calculated according to the method shown in FIG. 3. The power of the side heater, the power of the bottom heater and the power of the upper heater that meet the thermal equilibrium condition are 90-7-10, 70-30-10, 50-54-10, 30-77-10 and 10-102-10. The power of the bottom heater in the combination of these power is basically the same as the result of the thermal equilibrium diagram shown in FIG. 4 (that is, the power of the bottom heater corresponding to the intersection points of lines A, B, C, D and E (not shown) in the thermal equilibrium diagram and the horizontal line (not shown) where the power of the upper heater is fixed to 10 KW). Therefore, in the actual crystal growth, in order to grow the crystal smoothly, the power of each of the heaters can be directly selected or adjusted according to the thermal equilibrium diagram, or the power of each of the heaters can be directly selected or adjusted according to the (for example, linear) relationship of the power of each of the heaters reaching the thermal equilibrium condition in the thermal equilibrium diagram. For example, even if the power of each of the heaters selected according to the equilibrium diagram or the law presented by same does not enable the system to reach the thermal equilibrium due to error, it is only necessary to slightly adjust the power of each of the heaters or one or two thereof without randomly attempting or guessing to select the power of each of the heaters in a time-consuming manner within a large range of the power of each of the heaters, thus greatly saving the calculation amount and time, and accordingly being able to grow a crystal with better quality.

It is to be pointed out that although in the disclosure, the power of the side heater is set to 10, 30, 50, 70, 90 KW, and the power of the upper heater and the power of the bottom heater are constantly changed to calculate the thermal equilibrium diagram, in other embodiments, the power of the side heater can be set to another value to constantly change the power of the upper heater and the power of the bottom heater so as to calculate the thermal equilibrium diagram. That is, there are other lines that are basically parallel to lines A, B, C, D and E in the thermal equilibrium diagram shown in FIG. 4, and the points thereon also meet the thermal equilibrium condition.

It is also to be noted that the heat equilibrium diagram shown in FIG. 4 is obtained in the case where the crystal growth rate is 0.6 mm/min. In other embodiments, the crystal growth rate can be another value, and a similar thermal equilibrium diagram can be obtained. Therefore, in one embodiment, the thermal equilibrium diagram can be a plurality of thermal equilibrium diagrams related to the crystal growth rate. Therefore, during crystal growth, the thermal equilibrium diagram corresponding to the current crystal growth rate can be selected from the plurality of thermal equilibrium diagrams, and the power of each of the heaters is selected from the thermal equilibrium diagram to control the heater. It is also to be noted that the thermal equilibrium is shown in FIG. 4 as a thermal equilibrium area in a two-dimensional plane and a plurality of lines with fixed power of the side heater for convenience of explanation. However, in other embodiments, the thermal equilibrium diagram can have other forms, such as the form of a table and the form of an object in a three-dimensional space with the power of each of the heaters as the coordinate axis, such as a point, a line, a surface, and a body.

In the actual crystal growth process, the power of each of the heaters is selected according to the thermal equilibrium diagram in FIG. 4, which can ensure that a crystal can grow out. However, in order to grow a perfect crystal, both the crystal growth rate V and the temperature gradient G at the solid-liquid interface are required. Generally, 0.88-1.12 times a V/G theoretical value (C_{crit}=2.1*10⁻⁵ cm²/s·K=0.126 mm²/min·° C.) is a window area of the perfect crystal. That is, the range of the V/G value is 0.112-0.142 mm²/min·° C., and Gc>=Ge is required at the same time. A perfect crystal can grow out if these two conditions are met. Preferably, 0.92-1.1 times the V/G theoretical value is the window area of the perfect crystal. That is, the range of the V/G value is 0.117-0.139 mm²/min·° C. In the actual crystal growth process, the crystal growth rate v is equal to 0.4-0.8 mm/min. This range is the crystal growth rate range that enables the crystal to grow out stably, reliably and smoothly in most crystal growth systems at present. For other and future developed crystal growth systems, there can be crystal growth rates in other ranges. For example, the crystal growth rate can be higher, so that the crystal can grow faster and more efficiently.

In the case where the crystal growth rate is in the range of V=0.4-0.8 mm/min, in order to grow a perfect crystal, 7.14 K/mm>=G>=2.8 K/mm, that is, 7140 K/m>=G>=2800 K/m, and Gc>=Ge is required at the same time. In other embodiments, the crystal growth rate is in other ranges. Correspondingly, the range of the G value also changes correspondingly according to the range of the V/G value being 0.112-0.142 mm²/min·° C. or preferably, the range of the V/G value being 0.117-0.139 mm²/min·° C., and Gc>=Ge is still required at the same time.

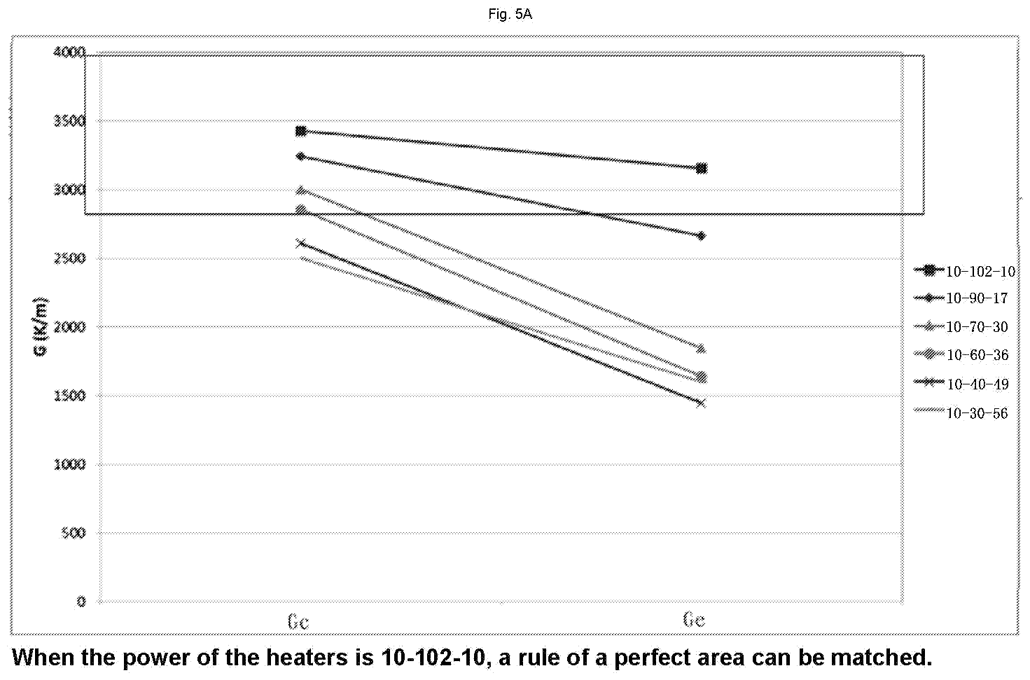

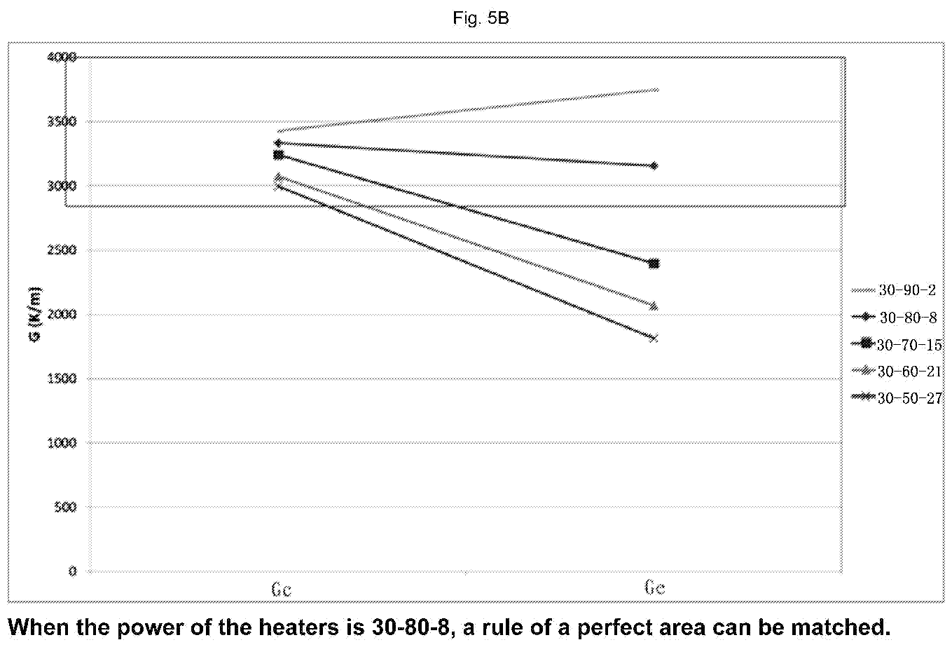

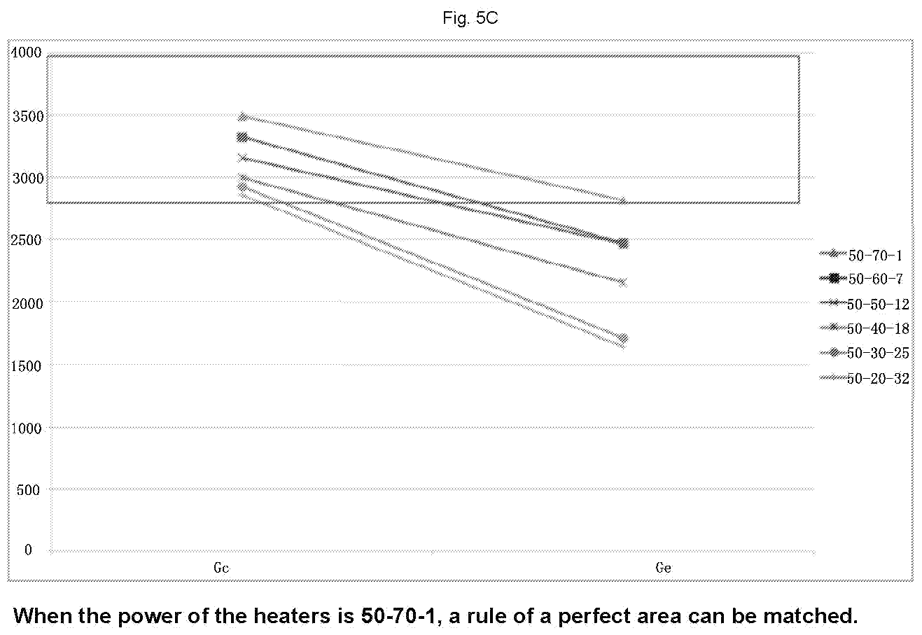

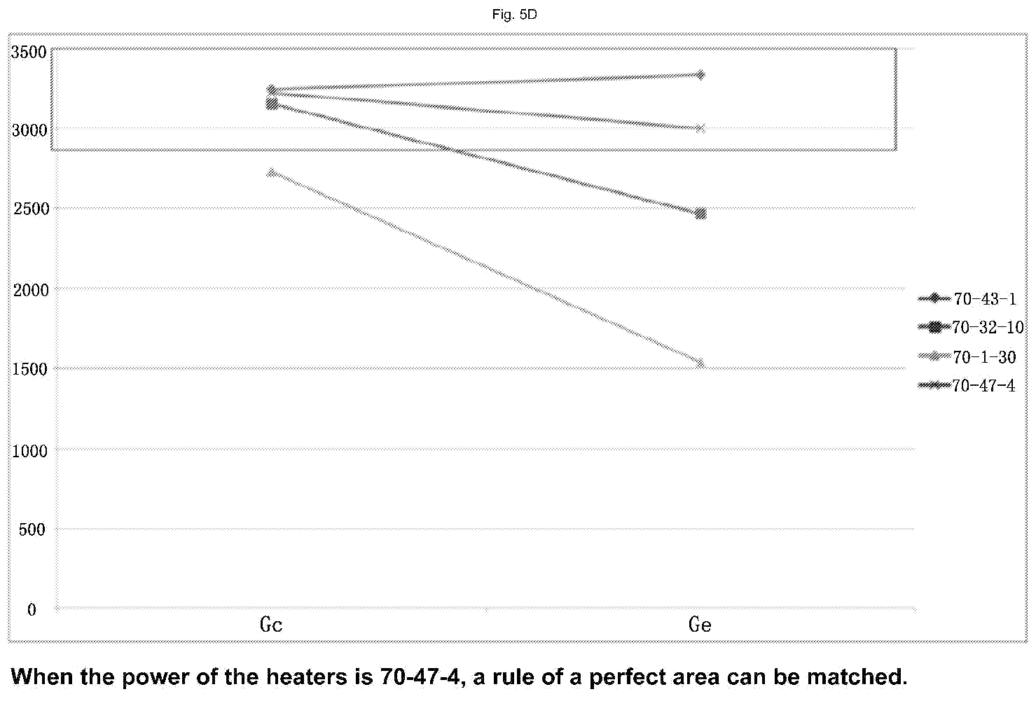

Now, referring to FIGS. 5A-5D, how to further select the power of each of the heaters meeting a perfect crystal growth condition from the thermal equilibrium diagram shown in FIG. 4 which meets the thermal equilibrium condition of the system is described. According to the power of each of the heaters meeting the thermal equilibrium of the system, the thermal field correspondingly distribution as well as the corresponding axial temperature gradient Ge at the edge and the axial temperature gradient Gc at the center of the crystal in the radial direction of the crystal can be calculated using a computer simulation method shown in FIG. 3. In one embodiment, the axial temperature gradients, including Ge and Gc, recorded at S120 in FIG. 3, corresponding to the power of each group of heaters meeting the thermal equilibrium condition can be directly retrieved from a memory. It is calculated whether the axial temperature gradient meets the above described G-value window which can correspond to the current crystal growth rate for growing a perfect crystal, and the condition that GC>=Ge. If so, each of the heaters is adjusted and controlled according to the corresponding power of each group of heater. That is, a perfect crystal can grow out. The calculation can be executed in a processor in the system 100 or a processor external to the system 100 or another computing device. It is to be noted that, due to the limitation of the scope, the G-value window of the perfect crystal shown in the upper part of FIGS. 5A-5D can only be a part of the whole window.

When the power of the side heater, the power of the bottom heater and the power of the upper heater are 10-102-10 KW, respectively, the conditions for growing a perfect crystal can be met at the same time, as shown in FIG. 5A. When the power of the side heater, the power of the bottom heater and the power of the upper heater are 30-80-8 KW, respectively, the conditions for growing a perfect crystal can be met at the same time, as shown in FIG. 5B. When the power of the side heater, the power of the bottom heater and the power of the upper heater are 50-70-1 KW, respectively, the conditions for growing a perfect crystal can be met at the same time, as shown in FIG. 5C. When the power of the side heater, the power of the bottom heater and the power of the upper heater are 70-47-4 KW, respectively, the conditions for growing a perfect crystal can be met at the same time, as shown in FIG. 5D. According to the corresponding power of each group of heater, a perfect crystal can grow out. It is to be pointed out that there can be power of multiple other groups of heaters meeting the condition for growing a perfect crystal. Moreover, in the actual crystal growth, when there is power of multiple groups of heaters that meet the thermal equilibrium condition or the condition for growing a perfect crystal at the same time, the power of one group of heater can be randomly selected therefrom, and the power of an optimal group of heater can also be selected to control the temperature gradient at the solid-liquid interface. In one embodiment, the power of the optimal group of heater can refer to the power of the group of heater that is closest to the current power of each of the heaters as a whole, so that the power of each of the heaters can be adjusted to expected power as quickly as possible. In one embodiment, the power of the optimal group of heater refers to the power of the following group of heater: after the heater is controlled according thereto, the thermal field distribution (specifically, the thermal field at the solid-liquid interface and vicinity thereof) of the system is closest to the current thermal field distribution, so that the change of the thermal field distribution of the system is minimal when the current power of each of the heaters is adjusted to the power of this group of heater. In other embodiments, the power of the optimal group of heater can meet another limiting condition.

By the method disclosed in the disclosure, during the crystal growth, the power of each of the heaters can be directly selected according to the thermal equilibrium diagram obtained in advance to control same so that a crystal can grow out. Furthermore, the crystal growth rate can be determined in real time, and the power of each of the heaters is directly selected according to the thermal equilibrium diagram corresponding to the determined crystal growth rate among the multiple thermal equilibrium diagrams related to the crystal growth rate to control same so that the crystal can grow out. Furthermore, the power of each of the heaters meeting the condition for growing the perfect crystal can be selected from the thermal equilibrium diagram so that the perfect crystal without crystal defects can grow out. Accordingly, the power of each of the heaters can be directly controlled according to the pre-calculated thermal equilibrium diagram during the crystal growth, and then the temperature gradient at the solid-liquid interface is controlled, thus, the calculation of the power of each of the heaters through the experimental site in actual production is avoided. And the calculation amount is greatly reduced, and the power of each of the heaters can be quickly and efficiently controlled, thereby improving the quality of the grown crystal.

It is to be clear to those skilled in the art that modifications and variations of the method and system according to the present disclosure are perceptible and fall within the scope of the present disclosure. The accompanying drawings are schematic. The specific embodiments described above with reference to the accompanying drawings are only illustrative and are not intended to limit the scope of the disclosure, which is defined by the appended claims.

1. A method for controlling temperature during crystal growth, comprising:
constantly adjusting power of each of heaters and performing simulating by software to calculate a thermal field correspondingly at a solid-liquid interface and vicinity of the solid-liquid interface;
enabling the thermal field to be coupled with a moving grid to determine whether the solid-liquid interface and a total thermal energy both reach thermal equilibrium;
storing the power of each of the heaters that enables both the solid-liquid interface and the total thermal energy to reach the thermal equilibrium and drawing a thermal equilibrium diagram based on the power of each of the heaters; and
selecting, during the crystal growth, the power of each of the heaters from the thermal equilibrium diagram which is drawn to control temperature gradient at the solid-liquid interface.

2. The method according to claim 1, further comprising keeping a liquid level of metal unchanged by continuous feeding during the crystal growth.

3. The method according to claim 1, wherein selecting, during the crystal growth, the power of each of the heaters from the thermal equilibrium diagram which is drawn comprises: selecting the power of each of the heaters that meets a condition for growing a perfect crystal from the thermal equilibrium diagram which is drawn during the crystal growth.

4. The method according to claim 3, wherein the condition for growing the perfect crystal comprises V/G=0.112−0.142 mm²/min·° C., and Gc>=Ge, wherein V represents a crystal growth rate, G represents axial temperature gradient at the solid-liquid interface, Gc represents G at a crystal center, and Ge represents G at a crystal edge.

5. The method according to claim 3, wherein the condition for growing the perfect crystal comprises V/G=0.117−0.139 mm²/min·° C., and Gc>=Ge, wherein V represents a crystal growth rate, G represents axial temperature gradient at the solid-liquid interface, Gc represents G at a crystal center, and Ge represents G at a crystal edge.

6. The method according to claim 1, further comprising determining a crystal growth rate in real time during the crystal growth.

7. The method according to claim 6, wherein the thermal equilibrium diagram is a plurality of thermal equilibrium diagrams corresponding to a plurality of crystal growth rates, wherein selecting, during the crystal growth, the power of each of the heaters from the thermal equilibrium diagram which is drawn comprises: selecting the power of each of the heaters from the thermal equilibrium diagram corresponding to the crystal growth rate determined in real time in the plurality of the thermal equilibrium diagrams during the crystal growth.

8. The method according to claim 6, wherein determining the crystal growth rate in real time comprises: detecting the crystal growth rate in real time using a sensor.

9. The method according to claim 6, wherein determining the crystal growth rate in real time comprises: retrieving a preset crystal growth rate from a device associated with the crystal growth.

10. The method according to claim 1, wherein constantly adjusting the power of each of the heaters comprises: adjusting the power of two or three different heaters selected from a group comprising a side heater, a bottom heater and an upper heater at a predetermined interval or randomly.

11. The method according to claim 1, wherein constantly adjusting the power of each of the heaters comprises: setting the power of one heater selected from a group comprising a side heater, a bottom heater and an upper heater to be each of a predetermined number of values, and adjusting the power of other two heaters in the group at a predetermined interval or randomly.

12. The method according to claim 1, wherein when the power of multiple groups of the heaters meeting a thermal equilibrium condition exists in the thermal equilibrium diagram, during the crystal growth, the power of one group of the heaters is randomly selected from the power of the multiple groups of the heaters to control the temperature gradient at the solid-liquid interface.

13. The method according to claim 1, wherein when the power of multiple groups of the heaters meeting a thermal equilibrium condition exists in the thermal equilibrium diagram, during the crystal growth, the power of one group of the heater, which is closest to current power of each of the heaters as a whole, is selected from the power of the multiple groups of the heaters to control the temperature gradient at the solid-liquid interface.

14. The method according to claim 1, wherein when the power of multiple groups of the heaters meeting a thermal equilibrium condition exists in the thermal equilibrium diagram, during the crystal growth, the power of following groups of the heater is selected from the power of the multiple groups of the heaters to control the temperature gradient at the solid-liquid interface: a thermal field distribution of a system is closest to a current thermal field distribution.

15. The method according to claim 1, wherein the thermal equilibrium diagram is in the form of a table that stores power of multiple groups of the heaters meeting a thermal equilibrium condition.

16. The method according to claim 1, wherein the thermal equilibrium diagram is in the form of a graph formed by connecting power of multiple groups of the heaters meeting a thermal equilibrium condition.

17. The method according to claim 1, wherein in the thermal equilibrium diagram, two of power of a side heater, power of a bottom heater and power of an upper heater are in a linear relationship, during the crystal growth, two of the power of the side heater, the power of the bottom heater and the power of the upper heater are adjusted according to the linear relationship.

18. A system for controlling temperature during crystal growth, comprising:
a single crystal furnace, comprising heaters and a continuous feeder configured to keep a liquid level of metal unchanged;
a processor;
a memory on which an instruction is stored, the instruction, when executed, causing the processor to execute the method according to claim 1; and
a controller coupled with the single crystal furnace, the heaters and the continuous feeder therein and the memory so as to control them.

19. The system according to claim 18, further comprising a sensor configured to detect a crystal growth rate in real time.

20. The method according to claim 2, further comprising determining a crystal growth rate in real time during the crystal growth.
